(19) United States
(12) Patent Application Publication
(10) Pub. No.: US 2025/0151339 A1
(43) Pub. Date: May 8, 2025

(54) MANUFACTURING METHOD FOR A THIN FILM TRANSISTOR SUBSTRATE AND A THIN FILM TRANSISTOR SUBSTRATE MANUFACTURED BY THE SAME

(71) Applicant: Samsung Display Co., LTD., Yongin-si (KR)

(72) Inventors: HYUNEOK SHIN, Yongin-si (KR); YUNJONG YEO, Yongin-si (KR)

(21) Appl. No.: 18/929,755

(22) Filed: Oct. 29, 2024

(30) Foreign Application Priority Data
Nov. 2, 2023 (KR) 10-2023-0149644

(51) Int. Cl. H01L 29/786; H01L 27/12

(52) U.S. Cl. CPC H10D 30/6758; H10D 86/0231; H10D 86/451; H10D 86/60

(57) ABSTRACT

A manufacturing method of a thin film transistor substrate includes forming an active pattern on a base substrate, forming a first insulating layer covering the active pattern, forming a gate pattern on the first insulating layer, forming a second insulating layer covering the gate pattern, forming a contact hole penetrating the first insulating layer and the second insulating layer and contacting the active pattern and forming a source-drain electrode in the contact hole. The first insulating layer and the second insulating layer include a first portion defining a first hole having a first opening width and a first height and a second portion having a second opening width, defining a second hole of the contact hole connected to the first hole disposed below the first hole, and having a second height. The first height is less than about ½ of the total height of the contact hole.

This application claims priority to Korean Patent Application No. 10-2023-0149644, filed on Nov. 2, 2023, and all the benefits accruing therefrom under 35 U.S.C. § 119, the content of which in its entirety is herein incorporated by reference.

### BACKGROUND

### 1. Field

The invention relates to a thin film transistor substrate, and more particularly to a thin film transistor substrate with high resolution.

### 2. Description of the Related Art

As information technology develops, the importance of display devices, which are a connecting medium between users and information, is emerging. For example, a use of liquid crystal display devices (“LCD”), organic light-emitting display devices (“OLED”), plasma display devices (“PDP”) and quantum dot display devices is increasing. The use of display devices such as the like is increasing.

A thin film transistor may be formed on a large-area substrate and is used in various display devices. The thin film transistor may include an active pattern, a gate pattern, and a source-drain electrode.

The source-drain electrode may be connected to the active pattern through a contact hole formed in an insulating layer. As the resolution of the display device increases, a critical dimension (“CD”) of the contact hole also becomes smaller.

### SUMMARY

Embodiments provide a manufacturing method of a thin film transistor substrate with high resolution.

Embodiments provide a thin film transistor substrate manufactured by the manufacturing method of the thin film transistor substrate.

In an embodiment, a manufacturing method of a thin film transistor substrate includes forming an active pattern on a base substrate, forming a first insulating layer covering the active pattern, forming a gate pattern on the first insulating layer, forming a second insulating layer covering the gate pattern, forming a contact hole penetrating the first insulating layer and the second insulating layer and contacting the active pattern and forming a source-drain electrode in the contact hole. The first insulating layer and the second insulating layer include a first portion defining a first hole of the contact hole having a first opening width and having a first height and a second portion having a second opening width, defining a second hole of the contact hole connected to the first hole below the first hole, and having a second height. The first height is less than about ½ of the total height of the contact hole.

In an embodiment, the forming of the contact hole may include forming a preliminary insulating layer on the active pattern to form the first insulating layer and the second insulating layer, disposing a first etch mask defining the second opening width on the preliminary insulating layer, etching a portion of the preliminary insulating layer using the first etch mask so that a top surface of the active pattern is not exposed, disposing a second etch mask defining the first opening width different from the second opening width on the preliminary insulating layer and etching the preliminary insulating layer using the second etch mask until the top surface of the active pattern is exposed by the second opening width.

In an embodiment, the first etch mask may be a pair of photoresist patterns.

In an embodiment, the second etch mask may be formed by isotropic etching of the first etch mask.

In an embodiment, each of the steps of etching the preliminary insulating layer may be dry etching.

In an embodiment, the first insulating layer and the second insulating layer may further include a third portion having a third opening width and may define a third hole connected to the second hole disposed below the second hole of the contact hole, and having a third height, where a sum of the first height and the second height may be less than about ½ of the total height of the contact hole.

In an embodiment, the forming of the contact hole may include forming a preliminary insulating layer on the active pattern to form the first insulating layer and the second insulating layer, disposing a first etch mask defining the second opening width on preliminary insulating layer, etching a portion of the preliminary insulating layer using the first etch mask so that a top surface of the active pattern is not exposed, disposing a second etch mask defining the first opening width different from the second opening width on the preliminary insulating layer, etching a portion of the preliminary insulating layer using the second etch mask so that a top surface of the active pattern is not exposed, disposing a third etch mask defining the third opening width different from the first opening width and second opening width on the preliminary insulating layer and etching the preliminary insulating layer using the third etch mask until the top surface of the active pattern is exposed by the third opening width.

In an embodiment, the first etch mask may be a pair of photoresist patterns.

In an embodiment, the second etch mask may be formed by isotropic etching of the first etch mask, and the third etch mask may be formed by isotropic etching of the second etch mask.

In an embodiment, each of the steps of etching the preliminary insulating layer may be dry etching.

In an embodiment, the active pattern may be formed of crystallized silicon (poly-Si), and the source-drain electrode may be formed of at least one of titanium and aluminum.

In an embodiment, the first insulating layer may be formed of at least one of silicon oxide, silicon nitride, silicon oxynitride, and aluminum oxide, and the second insulating layer may be formed of at least one of silicon oxide, silicon nitride, silicon oxynitride, and aluminum oxide.

In an embodiment, a thin film transistor substrate includes a base substrate, an active pattern disposed on the base substrate, a first insulating layer covering the active pattern, a gate pattern on the first insulating layer, a second insulating layer covering the gate pattern and a source-drain electrode disposed in a contact hole penetrating the first insulating layer and the second insulating layer and in contact with the active pattern. The first insulating layer and the second insulating layer includes a first portion defining a first hole of the contact hole having a first opening width and having a first height and a second portion having a second opening width, defining a second hole of the contact hole connected to the first hole below the first hole, and having a second height. The first height is less than about ½ of the total height of the contact hole.

In an embodiment, the first opening width and the second opening width may have different sizes.

In an embodiment, the first opening width may be greater than the second opening width.

In an embodiment, the first insulating layer and the second insulating layer may further include a third portion having a third opening width and may define a third hole connected to the second hole disposed below the second hole of the contact hole, and having a third height, where a sum of the first height and the second height may be less than about ½ of the total height of the contact hole.

In an embodiment, the first opening width, the second opening width, and the third opening width may have different sizes.

In an embodiment, the first opening width may be greater than the second opening width, and the second opening width may be greater than the third opening width.

In an embodiment, the active pattern may include crystallized silicon (poly-Si), and the source-drain electrode may include at least one of titanium and aluminum.

In an embodiment, the first insulating layer may include at least one of silicon oxide, silicon nitride, silicon oxynitride, and aluminum oxide, and the second insulating layer may include at least one of silicon oxide, silicon nitride, silicon oxynitride, and aluminum oxide.

In an embodiment, a manufacturing method of a thin film transistor substrate includes forming an active pattern on a base substrate, forming a first insulating layer covering the active pattern, forming a gate pattern on the first insulating layer, forming a second insulating layer covering the gate pattern, forming a contact hole penetrating the first insulating layer and the second insulating layer and contacting the active pattern and forming a source-drain electrode in the contact hole. The first insulating layer and the second insulating layer include a first portion defining a first hole of the contact hole having a first opening width and having a first height and a second portion having a second opening width, defining a second hole of the contact hole connected to the first hole and disposed below the first hole, and having a second height. The first height is less than about ½ of the total height of the contact hole. Accordingly, a problem of poor step coverage may be solved. In addition, the second width of the second portion is unrelated to the first width of the first portion, so that a layout design might not be changed.

In addition, the manufacturing method of thin film transistor substrate may dry etch the portion of the preliminary insulating layer using the pair of photoresist patterns. Accordingly, manufacturing cost may be reduced not using additional mask.

In addition, the manufacturing method of a thin film transistor substrate may control a size of the pair of photoresist patterns by isotropic etching. Accordingly, the manufacturing cost may be reduced by not using additional mask, and the process might not be changed.

### BRIEF DESCRIPTION OF THE DRAWINGS

Illustrative, non-limiting embodiments will be more clearly understood from the following detailed description taken in conjunction with the accompanying drawings.

FIG. 1 is a plan view of a display device, according to an embodiment.

FIG. 2 is a cross-sectional view taken along a line I-I′ of the display device of FIG. 1, according to an embodiment.

FIG. 3 is a cross-sectional view of a thin film transistor substrate, according to an embodiment.

FIG. 4 is a view illustrating a manufacturing method of the thin film transistor substrate of FIG. 3, according to an embodiment.

FIG. 5 is a view illustrating a manufacturing method of the thin film transistor substrate of FIG. 3, according to an embodiment.

FIG. 6 is a view illustrating a manufacturing method of the thin film transistor substrate of FIG. 3, according to an embodiment.

FIG. 7 is a view illustrating a manufacturing method of the thin film transistor substrate of FIG. 3, according to an embodiment.

FIG. 8 is a view illustrating a manufacturing method of the thin film transistor substrate of FIG. 3, according to an embodiment.

FIG. 9 is a view illustrating a manufacturing method of the thin film transistor substrate of FIG. 3, according to an embodiment.

FIG. 10 is a view illustrating a manufacturing method of the thin film transistor substrate of FIG. 3, according to an embodiment.

FIG. 11 is a cross-sectional view of a transistor substrate, according to a comparative embodiment.

FIG. 12 is a plan view illustrating a contact hole defined in the transistor substrate, according to the comparative embodiment of FIG. 11.

FIG. 13 is a plan view illustrating the source-drain electrode included in the transistor substrate, according to the comparative embodiment of FIG. 11.

FIG. 14 is a plan view illustrating the first contact hole defined in the transistor substrate of FIG. 10, according to an embodiment.

FIG. 15 is a plan view illustrating the source-drain electrode included in the transistor substrate of FIG. 10, according to an embodiment.

FIG. 16 is a cross-sectional view illustrating a thin film transistor substrate, according to an embodiment.

FIG. 17 is a view illustrating the manufacturing method of the thin film transistor substrate of FIG. 16, according to an embodiment.

FIG. 18 is a view illustrating the manufacturing method of the thin film transistor substrate of FIG. 16, according to an embodiment.

FIG. 19 is a view illustrating the manufacturing method of the thin film transistor substrate of FIG. 16, according to an embodiment.

FIG. 20 is a view illustrating the manufacturing method of the thin film transistor substrate of FIG. 16, according to an embodiment.

FIG. 21 is a view illustrating the manufacturing method of the thin film transistor substrate of FIG. 16, according to an embodiment.

FIG. 22 is a view illustrating the manufacturing method of the thin film transistor substrate of FIG. 16, according to an embodiment.

FIG. 23 is a view illustrating the manufacturing method of the thin film transistor substrate of FIG. 16, according to an embodiment.

FIG. 24 is a view illustrating the manufacturing method of the thin film transistor substrate of FIG. 16, according to an embodiment.

FIG. 25 is a view illustrating the manufacturing method of the thin film transistor substrate of FIG. 16, according to an embodiment.

### DETAILED DESCRIPTION

Embodiments of the invention now will be described more fully hereinafter with reference to the accompanying drawings, in which various embodiments are shown. Like reference numerals refer to like elements throughout.

It will be understood that when an element (or a region, a layer, a portion, or the like) is referred to as being related to another such as being “on”, “connected to” or “coupled to” another element, it may be directly disposed on, connected or coupled to the other element, or intervening elements may be disposed therebetween.

Like reference numerals or symbols refer to like elements throughout. In the drawings, the thickness, the ratio, and the size of the element are exaggerated for effective description of the technical contents. As used herein, the term “and/or” includes any and all combinations of one or more of the associated listed items.

The term “and/or,” includes all combinations of one or more of which associated configurations may define.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the scope of the inventive concept. Similarly, a second element, component, region, layer or section may be termed a first element, component, region, layer or section. As used herein, the singular forms, “a”, “an” and “the” are intended to include the plural forms as well, unless the context clearly indicates otherwise.

Also, terms of “below”, “on lower side”, “above”, “on upper side”, or the like may be used to describe the relationships of the elements illustrated in the drawings. These terms have relative concepts and are described on the basis of the directions indicated in the drawings.

It will be further understood that the terms “comprise”, “includes” and/or “have”, when used in this specification, specify the presence of stated features, integers, steps, operations, elements, components, and/or groups thereof, but do not preclude the presence or addition of one or more other features, integers, steps, operations, elements, components, and/or groups thereof. As used herein, being “disposed directly on” may mean that there is no additional layer, film, region, plate, or the like between a part and another part such as a layer, a film, a region, a plate, or the like. For example, being “disposed directly on” may mean that two layers or two members are disposed without using an additional member such as an adhesive member, therebetween.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

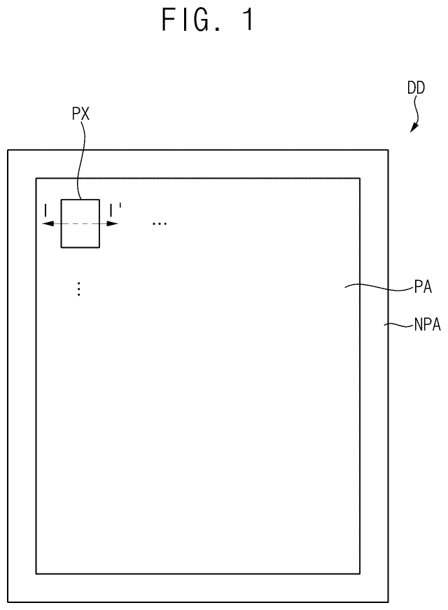

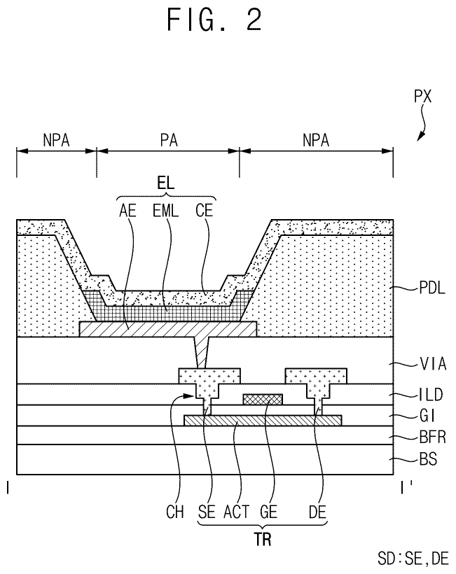

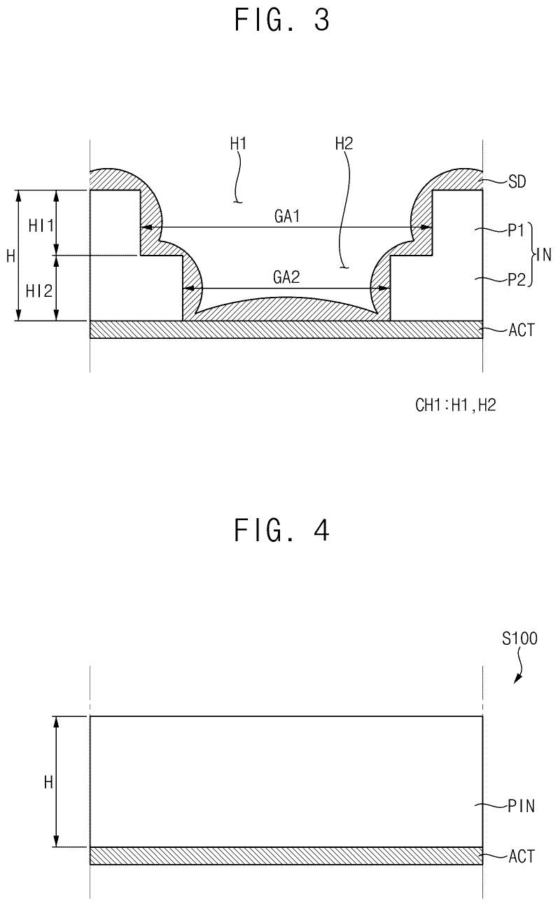

FIG. 1 is a plan view of a display device, according to an embodiment. FIG. 2 is a cross-sectional view taken along a line I-I′ of FIG. 1, according to an embodiment. FIG. 3 is a view illustrating a thin film transistor substrate, according to an embodiment.

In an embodiment and referring to FIG. 1, a display device DD may include a display area PA and a peripheral area NPA.

In an embodiment, the display area PA may be an area where an image is displayed. To this end, a plurality of pixels PX may be disposed in the display area PA.

In an embodiment, the peripheral area NPA may be an area where the image is not displayed. For example, a circuit structure (e.g., various wires, driving circuits, etc.) may be disposed in the peripheral area NPA. However, the invention is not limited thereto. For example, the plurality of pixels PX may be disposed in the peripheral area NPA.

In an embodiment, the peripheral area NPA may surround the display area PA. However, the invention is not limited thereto. In an embodiment, the peripheral area NPA may be omitted.

In an embodiment and referring to FIG. 2, each of the plurality of pixels PX may include a base substrate BS, a buffer layer BFR, at least one transistor TR, a first insulating layer GI, a second insulating layer ILD, a third insulating layer VIA, a light emitting element EL, and a pixel defining layer PDL. In an embodiment, the transistor TR may include an active pattern ACT, a gate pattern GE, and a source-drain electrode SD. In an embodiment, the light emitting element EL may include a first electrode AE, a light emitting layer EML, and a second electrode CE.

In an embodiment, the base substrate BS may include glass, quartz, plastic, etc. In an embodiment, the base substrate BS may have flexible, bendable, or rollable characteristics.

In an embodiment, the buffer layer BFR may be disposed on the base substrate BS. The buffer layer BFR may include an inorganic insulating material. For example, the buffer layer BFR may include silicon oxide, silicon nitride, silicon oxynitride, etc. The buffer layer BFR may serve to block impurities diffused from the base substrate BS to prevent the active pattern ACT of the transistor TR from being damaged by the impurities diffused from the base substrate BS.

In an embodiment, the active pattern ACT may be disposed on the base substrate BS. Specifically, the active pattern ACT may be disposed on the buffer layer BFR. The active pattern ACT may include a silicon semiconductor material. The active pattern ACT may include amorphous silicon, polycrystalline silicon, etc. In an embodiment, the active pattern ACT may include crystallized silicon (poly-Si). In another embodiment, the active pattern ACT may include an oxide semiconductor material. For example, the active pattern ACT may include zinc oxide, zinc-tin oxide, zinc-indium oxide, indium oxide, titanium oxide, indium-gallium-zinc oxide, indium-zinc-tin oxide, etc.

In an embodiment, the first insulating layer GI may cover the active pattern ACT. The first insulating layer GI may include an inorganic insulating material. For example, the first insulating layer GI may include silicon oxide, silicon nitride, silicon oxynitride, titanium oxide, tantalum oxide, etc. The first insulating layer GI may serve to electrically insulate the active pattern ACT and the gate pattern GE from each other.

In an embodiment, the gate pattern GE may be disposed on the first insulating layer GI. The gate pattern GE may include a conductive material. For example, the gate pattern GE may include metal, alloy, conductive metal oxide, transparent conductive material, etc. A gate signal may be applied to the gate pattern GE. The gate signal may control an electrical conductivity of the active pattern ACT by turning on/off the transistor TR.

In an embodiment, the second insulating layer ILD may cover the gate pattern GE. The second insulating layer ILD may include an organic insulating material and/or an inorganic insulating material. The second insulating layer ILD may serve to electrically insulate the source-drain electrode SD and the gate pattern GE.

In an embodiment and referring to FIG. 2 and FIG. 3, the first insulating layer GI and the second insulating layer ILD may include a first portion P1 and a second portion P2. In other words, an insulating layer IN may include the first portion P1 and the second portion P2.

In an embodiment, the first portion P1 may define a first hole H1 of a contact hole CH (e.g., a first contact hole CH1 of FIG. 3, a second contact hole CH2 of FIG. 16, etc.). The first hole H1 may have a first opening width GA1. The first portion P1 may have a first height HI1.

In an embodiment, the second portion P2 may define the second hole H2 of the contact hole CH (e.g., the first contact hole CH1 of FIG. 3, the second contact hole CH2 of FIG. 16, etc.). The second hole H2 may be connected to the first hole H1 below the first hole H1. In other words, the first contact hole CH1 may have a structure in which the second hole H2 and the first hole H1 are connected in a direction away from the active pattern ACT.

In an embodiment, the second hole H2 may have a second opening width GA2. In an embodiment, the first opening width GA1 and the second opening width GA2 may have different sizes. In an embodiment, the first opening width GA1 may be larger than the second opening width GA2. Accordingly, when the source-drain electrode SD is formed, overhang may be minimized, and disconnection of the source-drain electrode SD due to the overhang may be prevented.

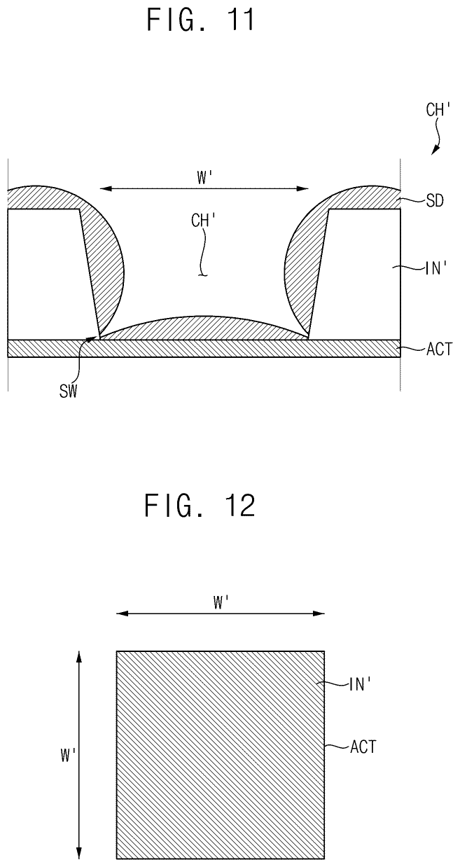

A detailed description of an effect of preventing the disconnection will be described below with reference to FIGS. 11, 12, 13, 14, and 15.

In an embodiment, the second portion P2 may have a second height HI2. The second height HI2 may be about ½ or more of a total height H of the first contact hole CH1. Therefore, when the insulating layer IN includes only the first portion P1 and the second portion P2, the first height HI1 of the first portion P1 may be about ½ or less of the total height H of the first contact hole CH1. In other words, the second height HI2 may be greater than or equal to the first height HI1.

In an embodiment, the insulating layer IN may be formed of silicon oxide (“SiO2”), silicon nitride (“SiNx”), silicon oxynitride (“SiON”), aluminum oxide (“Al₂O₃”), etc. These may be used alone or in combination with each other. However, the invention is not limited thereto. In another embodiment, the insulating layer IN may include various insulating materials.

In an embodiment, the first portion P1 and the second portion P2 may be formed using an etch selectivity of the material included in the insulating layer IN. However, the invention is not limited thereto. A detailed description of a method of forming the insulating layer IN including the first portion P1 and the second portion P2 using photoresist will be described below with reference to FIGS. 4, 5, 6, 7, 8, 9, and 10.

In an embodiment, the source-drain electrode SD (e.g., a source electrode SE and/or a drain electrode DE) may be disposed on the second insulating layer ILD. Each of the source-drain electrode SD may include a conductive material. For example, each of the source-drain electrode SD may include a metal, alloy, conductive metal oxide, transparent conductive material, etc. Each of the source-drain electrode SD may be in electrical contact with the active pattern ACT through a contact hole penetrating the second insulating layer ILD and the first insulating layer GI. The source-drain electrode SD may be disposed in the contact hole CH penetrating the first insulating layer GI and the second insulating layer ILD and in contact with the active pattern ACT (e.g., the first contact hole CH1 of FIG. 3, the second contact hole CH2 of FIG. 16, etc.).

In an embodiment, the source-drain electrode SD may include titanium (“Ti”), aluminum (“Al”), or the like. These may be used alone or in combination with each other. However, the invention is not limited thereto. For example, the source-drain electrode SD may include various metal materials.

In an embodiment, the third insulating layer VIA may be disposed on the source-drain electrode SD. The third insulating layer VIA may include an organic insulating material. For example, the third insulating layer VIA may include polyacrylic resin, polyimide resin, acrylic resin, etc. Accordingly, a top surface of the third insulating layer VIA may be substantially flat.

In an embodiment, the first electrode AE may be disposed on the third insulating layer VIA. The first electrode AE may include a conductive material. For example, the first electrode AE may include metal, alloy, conductive metal oxide, transparent conductive material, etc. The first electrode AE may be in electrical contact with the source electrode SE or the drain electrode DE through a contact hole penetrating the third insulating layer VIA.

In an embodiment, the pixel defining layer PDL may be disposed on the first electrode AE. The pixel defining layer PDL may include an organic insulating material. For example, the pixel defining layer PDL may include a polyacrylic compound, a polyimide compound, etc. The pixel defining layer PDL may partition a light emitting area of each of the plurality of pixels. To this end, the pixel defining layer PDL may define a pixel opening exposing the first electrode AE.

In an embodiment, the light emitting layer EML may be disposed on the first electrode AE in the pixel opening. The light emitting layer EML may include an organic light emitting material. For example, the light emitting layer EML may have a multi-layer structure including various functional layers. Additionally, the light emitting layer EML may further include at least one of a hole injection layer, a hole transport layer, an electron transport layer, and an electron injection layer.

In an embodiment, the second electrode CE may be disposed on the light emitting layer EML and cover the pixel defining layer PDL.

The display device DD described above with reference to FIGS. 1, 2, and 3 is an embodiment, and components included in the display device DD may be changed in various ways.

The display device DD has been described as including the first insulating layer GI, the second insulating layer ILD, and the third insulating layer VIA, however, in an embodiment, the display device DD may further include insulating layers. In another embodiment, the first insulating layer GI, the second insulating layer ILD, and the third insulating layer VIA may be omitted.

FIGS. 4, 5, 6, 7, 8, 9, and 10 are views illustrating a manufacturing method of the thin film transistor substrate of FIG. 3, according to an embodiment.

Hereinafter, descriptions overlapping with the thin film transistor substrate described above with reference to FIGS. 1, 2, and 3 will be omitted or simplified.

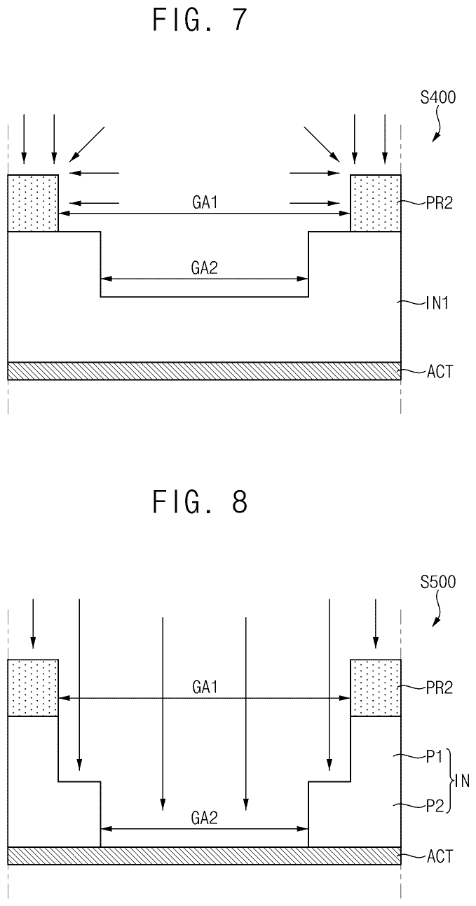

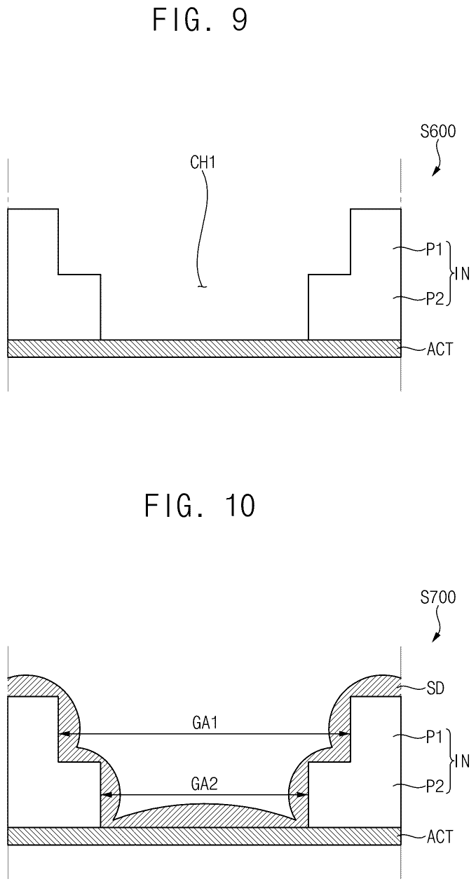

In an embodiment and as shown of FIG. 2, an active pattern ACT may be formed on the base substrate BS, the first insulating layer GI may be formed covering the active pattern ACT, and a first insulating layer GI is formed on the base substrate BS, the gate pattern GE may be formed on the first insulating layer GI, and the second insulating layer ILD may be formed covering the gate pattern GE (e.g., see S100 of FIG. 4). Next, the contact hole CH may be formed through the first insulating layer GI and the second insulating layer ILD to be in contact with the active pattern ACT (e.g., see S300 of FIG. 6, S400 of FIG. 7, S500 of FIGS. 8, and S600 of FIG. 9). Next, the source-drain electrode SD may be formed in the contact hole CH (e.g., see S700 of FIG. 10).

Hereinafter, a method of forming the first contact hole CH1 corresponding to the contact hole CH of FIG. 2 will be described with reference to FIGS. 4, 5, 6, 7, 8, 9, and 10.

In an embodiment and referring to FIG. 4, as an example, a preliminary insulating layer PIN may be formed on the active pattern ACT. The preliminary insulating layer PIN may form the first insulating layer GI and the second insulating layer ILD with reference to FIG. 2.

In an embodiment, the preliminary insulating layer PIN may be formed to have the total height H of the contact hole CH.

In an embodiment, the preliminary insulating layer PIN may be formed of silicon oxide (“SiO2”), silicon nitride (“SiNx”), silicon oxynitride (“SiON”), aluminum oxide (“Al2O3”), etc. These may be used alone or in combination with each other. However, the invention is not limited thereto. For example, the preliminary insulating layer PIN may include various materials.

In an embodiment, t, the preliminary insulating layer PIN may be formed by chemical vapor deposition (“CVD”). However, the invention is not limited thereto. For example, the preliminary insulating layer PIN may be formed in various ways, such as by a sputter method.

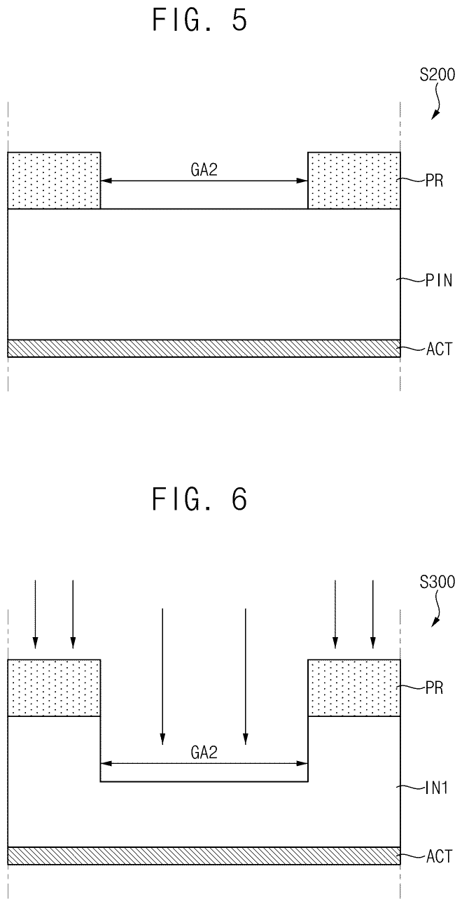

In an embodiment and referring to FIG. 5, a first etch mask PR defining the second opening width GA2 may be disposed on the preliminary insulating layer PIN (S200).

In an embodiment, the first etch mask PR may be a pair of photoresist patterns. In other words, the pair of photoresist patterns may be disposed on the preliminary insulating layer PIN to have a gap equal to the second opening width GA2.

In an embodiment, the first etch mask PR may be formed by forming a photoresist layer on the preliminary insulating layer PIN and performing an exposure process and a development process using a mask on the photoresist layer.

In an embodiment, the photoresist layer may be formed of either a positive type in which an area irradiated with ultraviolet rays (“UV”) is removed, or a negative type in which an area irradiated with ultraviolet rays (“UV”) remains.

In an embodiment, the mask may include a first area and a second area. The first area may correspond to a position where the pair of photoresist patterns are formed. The second area may correspond to a position where the pair of photoresist patterns are not formed. A light transmittance of the first area and the second area may be different from each other.

In an embodiment and referring to FIGS. 5 and 6, a portion of the preliminary insulating layer PIN may be etched using the first etch mask PR so that a top surface of the active pattern ACT is not exposed (S300).

In an embodiment, the step of etching the preliminary insulating layer may be a dry etching process. The dry etching process may be an anisotropic etching process.

In an embodiment, the first etch mask PR may prevent the etching. Accordingly, the portion of the preliminary insulating layer PIN covered by the first etch mask PR might not be relatively etched.

Accordingly, in an embodiment, the primary insulating layer IN1 may be formed from the portion of the preliminary insulating layer PIN that is removed. A hole having the second opening width GA2 may be formed in the preliminary insulating layer PIN in the portion where the first etch mask PR is not disposed.

In an embodiment, the anisotropic etching process may be performed so that the second height (e.g., the second height HI2 of FIG. 3) of the second portion (e.g., the second portion P2 of FIG. 3) having the second opening width GA2 is more than about ½ of the total height of the contact hole (e.g., the total height H of the first contact hole CH1 of FIG. 3). The second height may vary depending on the type of material included in the preliminary insulating layer PIN, etching process conditions (e.g., type of etching gas, etching time, etc.), etc.

Referring to FIG. 7, in an embodiment, a second etch mask PR2 defines the first opening width GA1 that is different from the second opening width GA2 on the preliminary insulating layer (e.g., the first insulating layer IN1) (S400).

In an embodiment, the second etch mask PR2 may be formed by isotropic etching the first etch mask PR.

In an embodiment, the isotropic etching may use oxygen (O2) as a processing gas. However, the invention is not limited thereto. The isotropic etching may use various processing gases.

In an embodiment, the pair of photoresist patterns may be made smaller through the isotropic etching process. Specifically, a thickness and a width of the pair of photoresist patterns may be reduced compared to before the isotropic etching process. Accordingly, the gap between the pair of photoresist patterns may be larger than the second opening width GA2.

In an embodiment, the isotropic etching process may be performed until the gap between the pair of photoresist patterns has the first opening width GA1.

Referring to FIGS. 7 and 8, in an embodiment, the preliminary insulating layer (e.g., the primary insulating film IN1) may be etched (S500).

In an embodiment, as described above, the step of etching the preliminary insulating layer may be the dry etching process. The dry etching process may be the anisotropic etching process.

Accordingly, in an embodiment, the insulating layer IN may be formed in which the portion of the preliminary insulating layer may be further removed. The hole (e.g., the first contact hole CH1 of FIG. 3) exposing the top surface of the active pattern ACT may be formed in the insulating layer IN in a portion where the second etch mask PR2 is not disposed.

In an embodiment, the anisotropic etching process may be performed until the top surface of the active pattern ACT is exposed as much as the second opening width GA2.

In an embodiment, the first contact hole CH1 may be formed in the insulating layer IN through the method described above. The insulating layer IN may have a step shape. Accordingly, the first contact hole CH1 may have a shape in which the width of the opening increases in the direction away from the active pattern ACT.

In an embodiment and referring to FIGS. 8 and 9, the second etch mask PR2 on the insulating layer IN may be removed (S600).

In an embodiment, the second etch mask PR2 may be removed in various ways. For example, the photoresist may be removed through an ashing process or the like. The photoresist may include a hydrocarbon polymer. Therefore, the photoresist may react with oxygen atoms and be converted into carbon monoxide (CO), carbon dioxide (CO2), water (H2O), etc. Carbon monoxide (CO), carbon dioxide (CO2), water (H2O), etc. may be volatilized and removed. However, the invention is not limited thereto. For example, the photoresist may be removed by a stripping process. The photoresist may be removed using sulfuric acid (H2SO4), hydrogen peroxide (H2O2), etc.

In an embodiment and referring to FIGS. 9 and 10, the source-drain electrode (SD) may be formed in the first contact hole CH1 (S700).

In an embodiment, the source-drain electrode SD may have a multi-layer structure. For example, the source-drain electrode SD may include a first electrode layer, a second electrode layer, and a third electrode layer. For example, the second electrode layer may be disposed on the first electrode layer. The third electrode layer may be disposed on the second electrode layer.

In an embodiment, the source-drain electrode SD may be formed of a conductive material. For example, the source-drain electrode SD may be formed of titanium (“Ti”), aluminum (“Al”), or the like. These may be used alone or in combination with each other.

In an embodiment, the first electrode layer may be formed of titanium (“Ti”). The second electrode layer may be formed of aluminum (“Al”). The third electrode layer may be formed of titanium (“Ti”).

In an embodiment, the source-drain electrode SD may be formed by chemical vapor deposition (“CVD”). However, the invention is not limited thereto. For example, the source-drain electrode SD may be formed in various ways, such as the sputter method.

However, the invention is not limited thereto. For example, a structure, shape, material, etc. of the source-drain electrode SD may be changed in various ways.

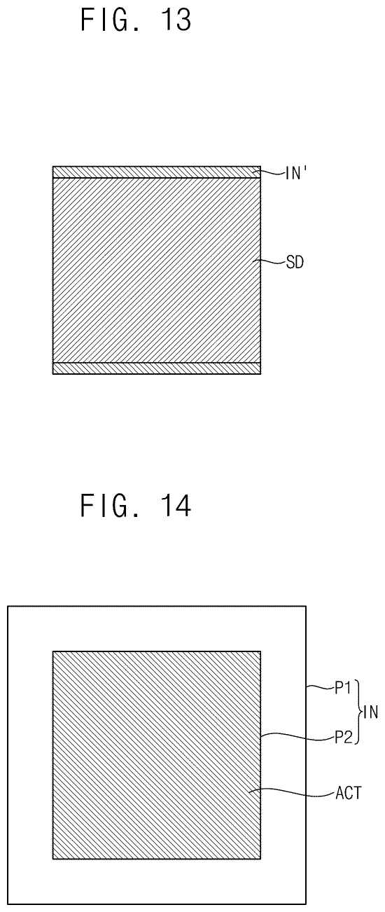

FIG. 11 is a cross-sectional view of a transistor substrate, according to a comparative embodiment. FIG. 12 is a plan view illustrating a contact hole defined in the transistor substrate of FIG. 11, according to the comparative embodiment of FIG. 11. FIG. 13 is a plan view illustrating the source-drain electrode included in the transistor substrate of FIG. 11, according to the comparative embodiment of FIG. 11.

Referring to FIGS. 11, 12, and 13, an insulating layer IN′ may be disposed on the active pattern ACT. A contact hole CH′ may be defined in the insulating layer IN′. A source-drain electrode SD may be disposed in the contact hole CH′ defined in the insulating layer IN′.

A width W′ of the contact hole CH′ may become narrower as a resolution increases. Accordingly, a contact defect may occur on a sidewall SW of the insulating layer IN′ located adjacent to the active pattern ACT. The contact defect may mean that the portion of the top surface of the active pattern ACT that is not covered by the insulating layer IN′ is not covered by the source-drain electrode SD.

As the resolution increases, the contact failure may occur more frequently. In other words, as the width W′ of the contact hole CH′ narrows, the contact defect may occur more frequently.

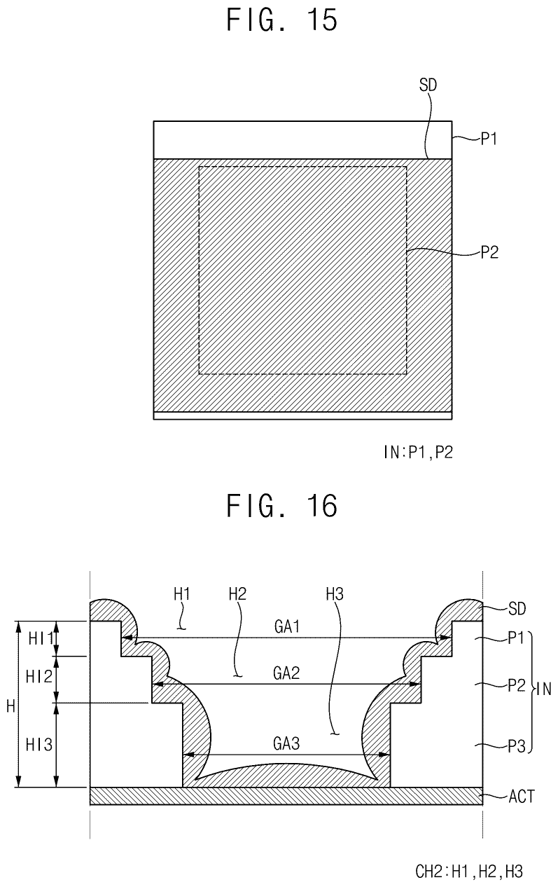

FIG. 14 is a plan view illustrating the first contact hole defined in the transistor substrate of FIG. 10, according to an embodiment. FIG. 15 is a plan view illustrating the source-drain electrode included in the transistor substrate of FIG. 10, according to an embodiment

In an embodiment and referring to FIGS. 10, 14, and 15, the insulating layer IN may be disposed on the active pattern ACT. The first contact hole CH1 may be defined in the insulating layer IN. The source-drain electrode SD may be disposed in the first contact hole CH defined in the insulating layer IN.

In an embodiment, in order to prevent the occurrence of the contact defect, the insulating layer IN may have the step shape. Accordingly, the first contact hole CH1 defined in the insulating layer IN may have a shape in which the width of the opening increases in the direction away from the active pattern ACT.

In an embodiment, as the first width GA1 of the first portion P1 increases, the top surface of the active pattern ACT not covered by the insulating layer IN may be completely covered by the source-drain electrode SD. In other words, a problem of poor step coverage may be solved.

In addition, in an embodiment, by maintaining the second width GA2 of the second portion P2 narrow, a high-resolution contact hole may be formed. For example, a width of the high-resolution contact hole may be about 1.3 micrometers (um) or less. Since the width GA2 of the second portion P2 is unrelated to the width GA1 of the first portion P1, a layout design might not be changed.

In addition, in an embodiment, the first contact hole CH1 may have the step shape using the photoresist. The photoresist may function as an etch-stop mask while its size is reduced by the isotropic etching. Accordingly, a manufacturing cost may be reduced by not using an additional mask.

FIG. 16 is a view illustrating a thin film transistor substrate, according to an embodiment.

Hereinafter, an overlapping description of the thin film substrate according to embodiments described above with reference to FIGS. 1, 2, and 3 and the manufacturing method of the thin film transistor substrate according to embodiments described above with reference to FIGS. 4, 5, 6, 7, 8, 9, and 10 will be omitted or simplified.

In an embodiment, the thin film transistor substrate of FIG. 16 may differ from the thin film transistor substrate of FIG. 3 only in the structure of the contact hole.

In an embodiment, the first insulating layer and the second insulating layer (e.g., the first insulating layer GI and the second insulating layer ILD of FIG. 2) may further include a third portion P3. In other words, the insulating layer IN may include the first portion P1, the second portion P2, and the third portion P3.

In an embodiment, the third portion P3 may define the third hole H3 of the second contact hole CH2. The third hole H3 may be connected to the second hole H2 and disposed below the second hole H2. In other words, the second contact hole CH2 may have a structure in which the third hole H3, the second hole H2, and the first hole H1 are connected in the direction away from the active pattern ACT.

In an embodiment, the third hole H3 may have a third opening width GA3. In an embodiment, the first opening width GA1, the second opening width GA2, and the third opening width GA3 may have different sizes. In an embodiment, the first opening width GA1 may be larger than the second opening width GA2, and the second opening width GA2 may be larger than the third opening width GA3. Accordingly, as described above, when the source-drain electrode SD is formed, the overhang may be minimized, and the occurrence of disconnection of the source-drain electrode SD due to the overhang may be prevented.

In an embodiment, the third portion P3 may have a third height HI3. The third height HI3 may be approximately ½ or more of the total height H of the first contact hole CH1. Therefore, when the insulating layer IN includes only the first portion P1, the second portion P2, and the third portion P3, the sum of the first height HI1 of the first portion P1 and the second height HI2 of the second portion P2 may be approximately ½ or less of the total height H of the first contact hole CH1. In other words, the third height HI3 may be greater than or equal to about the sum of the first height HI1 and the second height HI2.

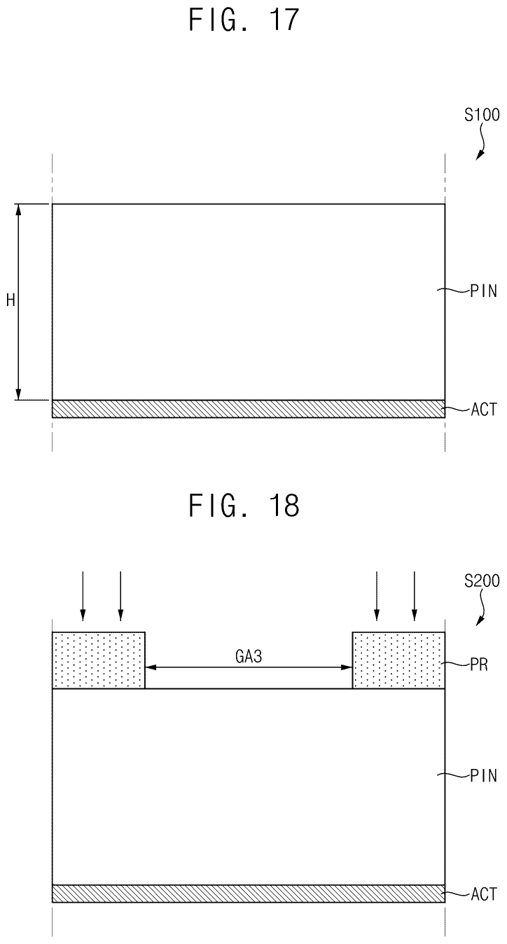

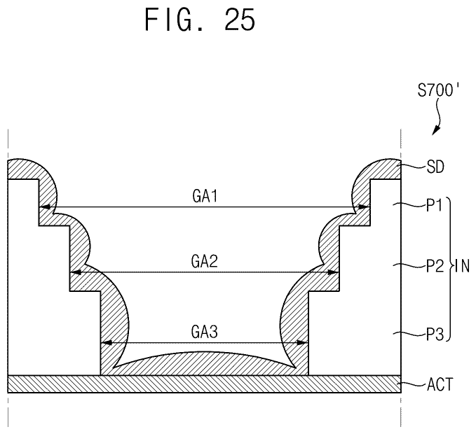

FIGS. 17, 18, 19, 20, 21, 22, 23, 24, and 25 are views illustrating the manufacturing method of the thin film transistor substrate of FIG. 16, according to an embodiment.

Hereinafter, descriptions overlapping with the thin film substrate described above with reference to FIGS. 1, 2, 3, and 16 and the manufacturing method of the thin film transistor substrate described above with reference to FIGS. 4, 5, 6, 7, 8, 9, and 10 will be omitted or simplified.

In an embodiment and referring to FIG. 17, the preliminary insulating layer PIN may be formed on the active pattern ACT (S100). For example, the preliminary insulating layer PIN may be formed to have the total height H of the contact hole CH.

In an embodiment and referring to FIG. 18, the first etch mask PR defining the third opening width GA3 may be disposed on the preliminary insulating layer PIN (S200).

In an embodiment, the first etch mask PR may be a pair of photoresist patterns. In other words, the pair of photoresist patterns may be arranged on the preliminary insulating layer PIN to have a gap equal to the third opening width GA3.

In an embodiment and referring to FIGS. 18 and 19, a portion of the preliminary insulating layer PIN may be etched using the first etch mask PR so that the top surface of the active pattern ACT is not exposed (S300).

Accordingly, in an embodiment, the primary insulating layer IN1 may be formed from which the portion of the preliminary insulating layer PIN is removed. A hole having the third opening width GA3 may be formed in the preliminary insulating layer PIN in the portion where the first etch mask PR is not disposed.

In an embodiment, the anisotropic etching process may be performed so that the third height (e.g., the third height HI3 of FIG. 16) of the third portion (e.g., the third portion P3 of FIG. 16) having the third opening width GA3 is more than about ½ of the total height of the contact hole (e.g., the total height H of the second contact hole CH2 of FIG. 16). The third height may vary depending on the type of material included in the preliminary insulating layer PIN, etching process conditions (e.g., type of etching gas, etching time, etc.), etc.

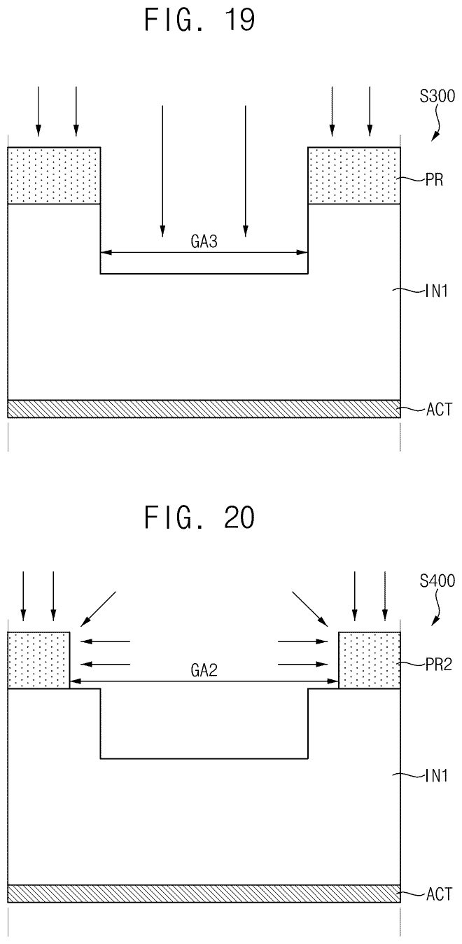

In an embodiment and referring to FIG. 20, the second etch mask PR2 defines the second opening width GA2 that is different from the third opening width GA3 on the preliminary insulating layer (e.g., the first insulating layer IN1) (S400).

In an embodiment, the pair of photoresist patterns may be made smaller through the isotropic etching process. Accordingly, the gap between the pair of photoresist patterns may be larger than the third opening width GA3.

In an embodiment, the isotropic etching process may be performed until the gap between the pair of photoresist patterns has the second opening width GA2.

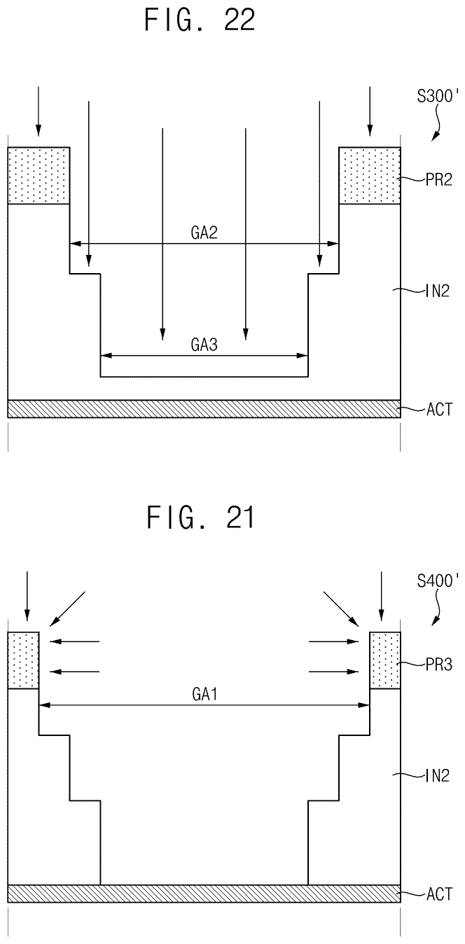

In an embodiment and referring to FIGS. 20 and 21, a portion of the preliminary insulating layer (e.g., primary insulating layer IN1) may be etched using the second etch mask PR2 to prevent the top surface of the active pattern ACT from being exposed (S300′).

Accordingly, in an embodiment, the second insulating layer IN2 may be formed from which the portion of the first insulating layer is removed. A hole having the step shape may be formed in the second insulating layer IN2 in the portion where the second etch mask PR2 is not disposed.

In an embodiment, the anisotropic etching process may be performed so that the third height (e.g., the third height HI3 of FIG. 16) of the third portion (e.g., the third portion P3 of FIG. 16) having the third opening width GA3 is more than about ½ of the total height of the contact hole (e.g., the total height H of the second contact hole CH2 of FIG. 15). The third height may vary depending on the type of material included in the preliminary insulating layer PIN, etching process conditions (e.g., type of etching gas, etching time, etc.), etc.

In an embodiment and referring to FIG. 22, a third etch mask PR3 define the second opening width (e.g., the second opening width GA2 of FIG. 21) that is different from the first opening width GA1 on the preliminary insulating layer (e.g., the second insulating layer IN2) (S400′).

In an embodiment, the pair of photoresist patterns may be made smaller through the isotropic etching process. Accordingly, the gap between the pair of photoresist patterns may be larger than the second opening width.

In an embodiment, the isotropic etching process may be performed until the gap between the pair of photoresist patterns has the first opening width GA1.

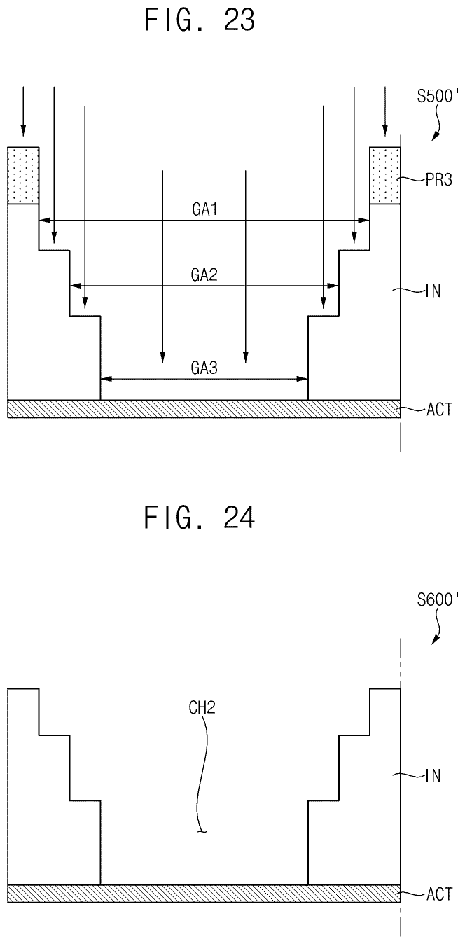

In an embodiment and referring to FIG. 23, the preliminary insulating layer (e.g., the second insulating film IN2) may be etched using the third etch mask PR3 until the top surface of the active pattern ACT is exposed by the third opening width GA3 (S500).

In an embodiment, as described above, the step of etching the preliminary insulating layer may be the dry etching process. The dry etching process may be the anisotropic etching process.

Accordingly, in an embodiment, the insulating layer IN in which the portion of the second insulating layer is further removed may be formed. A hole (e.g., the second contact hole CH2 of FIG. 16) exposing the top surface of the active pattern ACT may be formed in the insulating layer IN in the portion where the third etch mask PR3 is not disposed.

In an embodiment, the isotropic etching may be performed until the top surface of the active pattern ACT is exposed by the third opening width GA3.

In an embodiment, the second contact hole CH2 may be formed in the insulating layer IN through the method described above. The insulating layer IN may have the step shape. Accordingly, the second contact hole CH2 may have the shape in which the width of the opening increases in the direction away from the active pattern ACT.

In an embodiment and referring to FIGS. 23, 24, and 25, the third etch mask PR3 on the insulating layer IN may be removed (S600′). Next, the source-drain electrode SD may be formed in the second contact hole CH2 (S700′).

In the embodiments above, it has been described that the first contact hole includes the first portion and the second portion, and the second contact hole includes the first portion, the second portion, and the third portion, however, the invention is not limited thereto.

For example, in an embodiment, between the step of etching a portion of the preliminary insulating layer so that the top surface of the active pattern is not exposed using the first etch mask and the step of etching the preliminary insulating layer until the top surface of the active pattern ACT is exposed using an n-th mask, the step of disposing the n-th mask define a n-th opening width and step of etching a portion of the preliminary insulating layer using the n-th mask to prevent the top surface of the active pattern from being exposed may be repeated and then the insulating layer including the first to n-th portion may be formed. Accordingly, the contact hole may have further complex step shapes. In other words, in an embodiment, a width of an upper opening may be made large while a width of the lower opening adjacent to the active pattern ACT is kept narrow.

In an embodiment, the thin film transistor substrate may be applied to the display devices included in computers, laptops, mobile phones, smartphones, smart pads, PMPs, PDAs, MP3 players, or the like

Embodiments of the invention should not be construed as being limited to the embodiments set forth herein. Rather, these embodiments are provided so that this disclosure will be thorough and complete and will fully convey the concept of the invention to those skilled in the art. While the invention has been particularly shown and described with reference to embodiments thereof, it will be understood by those of ordinary skill in the art that various changes in form and details may be made therein without departing from the spirit or scope of the invention. Moreover, the embodiments or parts of the embodiments may be combined in whole or in part without departing from the scope of the invention.

What is claimed is:

1. A manufacturing method of a thin film transistor substrate, the method comprising:
forming an active pattern on a base substrate;
forming a first insulating layer covering the active pattern;
forming a gate pattern on the first insulating layer;
forming a second insulating layer covering the gate pattern;
forming a contact hole penetrating the first insulating layer and the second insulating layer and contacting the active pattern; and
forming a source-drain electrode in the contact hole, wherein,
the first insulating layer and the second insulating layer include:
a first portion defining a first hole of the contact hole having a first opening width and having a first height; and
a second portion having a second opening width, defining a second hole of the contact hole connected to the first hole and disposed below the first hole, and having a second height, and
wherein the first height is less than about ½ of the total height of the contact hole.

2. The method of claim 1, wherein the forming of the contact hole comprises:
forming a preliminary insulating layer on the active pattern to form the first insulating layer and the second insulating layer;
disposing a first etch mask defining the second opening width on the preliminary insulating layer;
etching a portion of the preliminary insulating layer using the first etch mask so that a top surface of the active pattern is not exposed;
disposing a second etch mask defining the first opening width different from the second opening width on the preliminary insulating layer; and
etching the preliminary insulating layer using the second etch mask until the top surface of the active pattern is exposed by the second opening width.

3. The method of claim 2, wherein the first etch mask is a pair of photoresist patterns.

4. The method of claim 2, wherein the second etch mask is formed by isotropic etching of the first etch mask.

5. The method of claim 2, wherein each of the steps of etching the preliminary insulating layer is dry etching.

6. The method of claim 1, wherein,
the first insulating layer and the second insulating layer further include a third portion having a third opening width to define a third hole connected to the second hole disposed below the second hole of the contact hole, and having a third height, and
where a sum of the first height and the second height is less than about ½ of the total height of the contact hole.

7. The method of claim 6, wherein the forming of the contact hole comprises:
forming a preliminary insulating layer on the active pattern to form the first insulating layer and the second insulating layer;
disposing a first etch mask defining the second opening width on the preliminary insulating layer;
etching a portion of the preliminary insulating layer using the first etch mask so that a top surface of the active pattern is not exposed;
disposing a second etch mask defining the first opening width different from the second opening width on the preliminary insulating layer;
etching a portion of the preliminary insulating layer using the second etch mask so that a top surface of the active pattern is not exposed;
disposing a third etch mask defining the third opening width different from the first opening width and second opening width on the preliminary insulating layer; and
etching the preliminary insulating layer using the third etch mask until the top surface of the active pattern is exposed by the third opening width.

8. The method of claim 7, wherein the first etch mask is a pair of photoresist patterns.

9. The method of claim 7, wherein,
the second etch mask is formed by isotropic etching of the first etch mask, and
the third etch mask is formed by isotropic etching of the second etch mask.

10. The method of claim 7, wherein each of the steps of etching the preliminary insulating layer is dry etching.

11. The method of claim 1, wherein,
the active pattern is formed of crystallized silicon (poly-Si), and
the source-drain electrode is formed of at least one of titanium and aluminum.

12. The method of claim 1, wherein,
the first insulating layer is formed of at least one of silicon oxide, silicon nitride, silicon oxynitride, and aluminum oxide, and
the second insulating layer is formed of at least one of silicon oxide, silicon nitride, silicon oxynitride, and aluminum oxide.

13. A thin film transistor substrate comprising:
a base substrate;
an active pattern disposed on the base substrate;
a first insulating layer covering the active pattern;
a gate pattern disposed on the first insulating layer;
a second insulating layer covering the gate pattern; and
a source-drain electrode disposed in a contact hole penetrating the first insulating layer and the second insulating layer and in contact with the active pattern, wherein,
the first insulating layer and the second insulating layer include:
a first portion defining a first hole of the contact hole having a first opening width and having a first height; and
a second portion having a second opening width, defining a second hole of the contact hole connected to the first hole below the first hole, and having a second height, and
wherein the first height is less than about ½ of the total height of the contact hole.

14. The thin film transistor substrate of claim 13, wherein the first opening width and the second opening width have different sizes.

15. The thin film transistor substrate of claim 14, wherein the first opening width is greater than the second opening width.

16. The thin film transistor substrate of claim 13, wherein,
the first insulating layer and the second insulating layer further include a third portion having a third opening width to define a third hole connected to the second hole disposed below the second hole of the contact hole, and having a third height, and
where a sum of the first height and the second height is less than about ½ of the total height of the contact hole.

17. The thin film transistor substrate of claim 16, wherein the first opening width, the second opening width, and the third opening width have different sizes.

18. The thin film transistor substrate of claim 16, wherein,
the first opening width is greater than the second opening width, and
the second opening width is greater than the third opening width.

19. The method of claim 14, wherein,
the active pattern includes crystallized silicon (poly-Si), and
the source-drain electrode includes at least one of titanium and aluminum.

20. The method of claim 14, wherein,
the first insulating layer includes at least one selected of silicon oxide, silicon nitride, silicon oxynitride, and aluminum oxide, and
the second insulating layer includes at least one of silicon oxide, silicon nitride, silicon oxynitride, and aluminum oxide.
